(19) United States
(12) Patent Application Publication
(10) Pub. No.: US 2023/0273248 A1
(43) Pub. Date: Aug. 31, 2023

(54) DEVICE, SYSTEM AND METHOD FOR DETERMINING ERROR SIGNAL WINDOWS IN A MEASUREMENT SIGNAL

(71) Applicant: MASCHINENFABRIK REINHAUSEN GMBH, Regensburg (DE)

(72) Inventors: Erik WINKELMANN, Dresden (DE); Christoph STEINER, Ottendorf-Okrilla (DE)

(21) Appl. No.: 18/043,050

(22) PCT Filed: Aug. 9, 2021
(86) PCT No.: PCT/EP2021/072132

§ 371 Date: Feb. 27, 2023

(30) Foreign Application Priority Data
Sep. 1, 2020 (DE) 10 2020 122 792.2

(51) Int. Cl. G01R 19/25

(52) U.S. Cl. CPC G01R 19/2513

(57) ABSTRACT

A device receives a measurement signal, and assigns samples thereof to signal window formed from a portion of a sequence of the samples. During initialization, signal windows are determined as initialization windows, and therefrom noise windows are determined and analyzed using an Xth-order model. Initial coefficient tuples are assigned to each noise window, and noise tuples are ascertained therefrom. During examination, signal windows are determined as measurement windows, which use the Xth-order model. The associated coefficients that form a measurement tuple assigned to each of the measurement windows are ascertained, as is a distance of the associated measurement tuple from the noise tuple for each of the measurement windows. The measurement windows whose associated measurement tuple is at a respective distance from the noise tuple that is greater than a limit value are determined as error signal windows representing a signal error.

### CROSS REFERENCE TO RELATED APPLICATIONS

This application is a U.S. National Phase application under 35 U.S.C. § 371 of International Application No. PCT/EP2021/072132, filed on Aug. 9, 2021, and claims benefit to German Patent Application No. DE 10 2020 122 792.2, filed on Sep. 1, 2020. The International Application was published in German on Mar. 10, 2022 as WO 2022/048863 A1 under PCT Article 21(2).

### FIELD

The present disclosure relates to a device, system, and method for determining error signal windows in a measurement signal.

### BACKGROUND

Electrical equipment can be designed to transmit electric power. The electrical equipment can, for example, be an electrical cable having multiple lines that is used to transmit electric power. Other electrical equipment can also be used to transmit electric power, such as transformers, or else to quantify current and voltage, such as electrical converters or overhead lines. The electrical equipment is preferably a cable for high-voltage direct current transmission or for high-voltage alternating current transmission. If a high voltage is used to transmit electric power, partial discharge (TE for short) can occur. Partial discharge refers to a locally limited electrical discharge that partially bypasses insulation between conductors, in particular of the aforementioned cable. Partial discharges can occur, for example, as a result of defects in the conductor and/or as a result of inhomogeneities in the insulation of the cables. If a partial discharge occurs, this causes a signal representing the partial discharge and containing an associated signal pattern, which is also transmitted by the electrical equipment. In this case, however, the transmission takes place from the location of the partial discharge to a connection point of the equipment. The signal caused by the partial discharge must therefore cover a certain transmission distance before the signal caused by the partial discharge can be detected at the connection point of the electrical equipment. Inductive, capacitive and/or resistive elements of the electrical equipment can cause attenuation and/or deformation of the signal caused by the partial discharge. At the connection point, therefore, it is often possible for only an attenuated and/or deformed signal caused by the partial discharge to be detected by sensors. The signal caused by the partial discharge can also be referred to as an error signal component of a measurement signal, or as an error signal for short. Other error signals can also be caused by other faults in the electrical equipment.

In order to establish whether a fault has occurred during the electric power transmission by means of electrical equipment, in practice a measurement signal that can be detected at a connection point of the electrical equipment is often recorded and then examined manually, for example using an oscilloscope, to establish whether a fault has occurred in the electrical equipment during the electric power transmission. However, this procedure is not tolerant of possible miscalculations and is also very time-consuming.

### SUMMARY

In an embodiment, the present disclosure provides a device that has an input signal interface configured to receive a digital measurement signal, containing a sequence of samples, that represents a signal detected at a connection point of electrical equipment; and a processor. The processor is configured to assign each sample of the measurement signal a respective signal window formed from a respective portion of the sequence of samples of the measurement signal containing the respective sample and a predetermined number of temporally preceding samples of the measurement signal. The processor is further configured so as, in an initialization phase, to determine a number of M signal windows as initialization windows and, from the M initialization windows, to determine a number of K noise windows, to analyze each of the K noise windows using a predetermined Xth-order model, and to ascertain the associated coefficients that form an initial coefficient tuple assigned to the respective noise window of the K noise windows, and to ascertain an expected value as a noise tuple from the initial coefficient tuples of the K noise windows, X being an even number between one and five. The processor is further configured so as, in an examination phase, to determine a plurality of the M signal windows as measurement windows, to analyze each of the measurement windows using the predetermined Xth-order model, and to ascertain the associated coefficients that form a measurement tuple assigned to each of the respective measurement windows, to ascertain a distance of the associated measurement tuple from the noise tuple for each of the measurement windows, and to determine, from the plurality of measurement windows, the measurement windows whose associated measurement tuple is at a respective distance from the noise tuple that is greater than a first, predetermined limit value G as error signal windows, with the result that each error signal window represents a signal error of the measurement signal.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an advantageous embodiment of the device and the system in a schematic representation;

FIG. 2 shows an illustrative distribution of a plurality of coefficient tuples;

FIG. 3 shows an illustrative detail from a measurement signal;

FIG. 4 shows an illustrative embodiment of the method in a schematic flowchart; and

FIG. 5 shows a further advantageous embodiment of the method in a schematic flowchart.

### DETAILED DESCRIPTION

Aspects of the present disclosure provide a device, a system, and a method that allow efficient and fault-tolerant detection of faults during the electric power transmission by means of electrical equipment.

According to a first aspect of the present disclosure, a device is provide that has an input signal interface for receiving a digital measurement signal that represents an analog signal detected at a connection point of electrical equipment. The digital measurement signal is a sequence of samples of the detected signal. In addition, the device has a processor unit configured to assign each sample of the measurement signal a respective signal window formed from a respective portion of the sequence of samples of the measurement signal containing the respective sample and a predetermined number of temporally preceding samples of the measurement signal. The processor unit is configured so as, in an initialization phase, to determine a number of M signal windows as initialization windows and from these M initialization windows a number of K noise windows, to analyze each noise window by means of a predetermined Xth-order model and to ascertain the associated coefficients that form an initial coefficient tuple assigned to the respective noise window, and to ascertain an expected value as a noise tuple from the initial coefficient tuple of the noise windows, X being an even number between one and five. Moreover, the processor unit is configured so as, in an examination phase, to determine a plurality of the signal windows as measurement windows, to analyze each measurement window by means of the predetermined Xth-order model and to ascertain the associated coefficients that form a measurement tuple assigned to the respective measurement window, to ascertain a distance of the associated measurement tuple from the noise tuple for each measurement window, and to determine from the plurality of measurement windows the measurement windows whose associated measurement tuple is at a respective distance from the noise tuple that is greater than a first, predetermined limit value as error signal windows. It follows from this that each error signal window represents a signal error of the measurement signal. The signal error can be an error signal component of the measurement signal.

When electric power is transmitted by means of the electrical equipment, a signal can be detected at the connection point that indicates the voltage that is present during the power transmission, the electrical power that is present during the power transmission, the electrical current that is present during the power transmission and/or another value representing the electric power transmission. The detected signal preferably represents the time characteristic of the energy transmitted by means of the electrical system, of the associated current, of the associated voltage and/or of the associated power. The digital measurement signal, which is made available to the input signal interface of the device, represents the signal detected at the connection point of the electrical equipment. The digital measurement signal is formed by a sequence of samples of the detected signal. The digital measurement signal is referred to as the measurement signal for short.

Often, however, the measurement signal represents not only the electrical energy (or associated current, associated voltage and/or associated power) transmitted by the electrical equipment, but also noise caused by the environment, and also error signals that can be present as a result of faults during the power transmission by means of the electrical equipment.

The configuration of the processor unit of the device is based on the fundamental idea that the noise differs from the error signal component of the measurement signal that is caused by a fault during the power transmission by means of the electrical equipment. In an initialization phase, therefore, an initial coefficient tuple that is characteristic of the noise occurring during the power transmission should first be ascertained by means of a mathematical model. The model is used to model the transfer function, or the transmission distance, of the electrical equipment during the power transmission. Depending on the adjustment of the coefficients, the model can be matched to the respective transmission properties of the electrical equipment. The processor unit is preferably configured to adjust the coefficients of the model on the basis of a signal window in such a way that the model approximates the actual transfer function of the electrical equipment as exactly as possible.

The processor unit is also configured to determine a number of M signal windows as initialization windows in the initialization phase. These M signal windows are preferably assigned to a corresponding number of M samples. These M samples are preferably M successive samples of the measurement signal. The measurement signal can have a useful component, an error signal component and a noise component. The useful component represents the electric power transmission, the associated voltage, the associated current and/or the associated power during the electric power transmission. The error signal component can be caused by possible faults during the electric power transmission and the noise component can represent the noise occurring during the electric power transmission and/or the measurement of the measurement signal. The processor unit is therefore preferably configured to determine a number of K noise windows from the M initialization windows. For this purpose, the processor unit can, for example, determine each of the M initialization windows in terms of the associated spectrum, a signal energy in the portion of the measurement signal that is represented by the respective initialization window, the number of zero crossings in the portion of the measurement signal that is represented by the respective initialization window and/or other analysis parameters, with the result that for example the spectrum, the signal energy, the number of zero crossings and/or the analysis parameters are used by the processor unit to determine which of the M initialization windows should be rated as noise windows. In this way, the processor unit can determine the K noise windows, for example. For each of the noise windows, it is assumed that the respective noise component is particularly large, or dominant.

The processor unit is configured to analyze each noise window by means of a predetermined Xth-order model and thereby to ascertain the associated coefficients. The coefficients are therefore the coefficients of the predetermined model. The coefficients can also be referred to as model coefficients. The model is preferably a mathematical model. The model can be designed to represent the partial signal formed by a signal window by adjusting the associated coefficients. The analysis carried out by the processor unit for each noise window adjusts the model, by way of the adjustment of the associated coefficients, in each case in such a way as to represent the partial signal represented by the respective noise window as exactly as possible. Preferably, X is the even number 2. This makes it particularly efficient and quick to analyze each noise window, or each partial signal represented by a noise window, by means of the predetermined model in such a way as to ascertain the associated coefficients of the model. As a result, each noise window is assigned coefficients, which are collectively referred to as initial coefficient tuples per noise window. Each noise window therefore has exactly one assigned dedicated initial coefficient tuple.

The processor unit is configured to ascertain an expected value as a noise tuple from the applicable number of K initial coefficient tuples. The noise tuple can be the arithmetic mean of the initial coefficient tuples. If each initial coefficient tuple is formed by a vector of multiple coefficients, the noise tuple can be ascertained, for example, by adding the applicable vectors and by then dividing the result by the number of initial coefficient tuples. The processor unit can be designed for this purpose. The noise tuple can thus form the expected value for the initial coefficient tuples. The noise tuple can also be understood as the noise center for the initial coefficient tuples. This is because the initial coefficient tuples are in a distributed arrangement around the noise tuple in geometric space.

In the initialization phase, the processor unit determines a number of M signal windows as initialization windows. The initialization phase is followed by the examination phase. The processor unit is therefore configured to determine a plurality of the signal windows as measurement windows in the examination phase. The measurement windows preferably differ from the signal windows that have previously been determined in the initialization phase. The plurality of measurement windows is preferably significantly greater than the number of initialization windows. An idea of the present disclosure is to identify several of the measurement windows as error signal windows in the examination phase, each representing a signal error in the portion of the measurement signal that is represented by the respective signal window. It therefore makes sense for the number of measurement windows to be significantly greater than the number of initialization windows.

The processor unit is configured so as, in the examination phase, to analyze each measurement window by means of the Xth-order predetermined model in order to ascertain the associated coefficients. Each measurement window is therefore analyzed by means of the same predetermined Xth-order model as was also already used to analyze the noise windows in the initialization phase. The analysis of the measurement windows can thus be carried out analogously to the analysis of the noise windows by means of the processor unit. Each measurement window is therefore analyzed by the processor unit by means of the Xth-order model in such a way that the associated coefficients of the model are ascertained. The coefficients ascertained for each measurement window are referred to as measurement tuples and are assigned to the respective measurement window. If the predetermined model is of the second order, two coefficients per measurement window are also ascertained in each case. If the model is of a higher order, however, then a number of coefficients per measurement window corresponding to the order is ascertained. If a measurement tuple is ascertained for a measurement window, the measurement tuple is at a specific distance in geometric space from the noise tuple that was ascertained in the initialization phase. A dimension of the geometric space can correspond to the order of the model. If the predetermined model is of a higher order, in particular third, fourth or fifth order, then the distance can be a distance defined in the corresponding space. The processor unit is configured to ascertain an associated distance of the respective measurement tuple from the noise tuple for each measured value. Thus, the number of measurement windows is taken as a basis for ascertaining a corresponding number of measurement tuples and a corresponding number of distances by means of the processor unit. If a measurement tuple is at a short distance from the noise tuple, the associated measurement window will very likely represent a portion of the measurement signal containing a large noise component. However, if the distance between the measurement tuple and the noise tuple is greater, in particular greater than a first, predetermined limit value, the assigned measurement window will very probably represent a portion of the measurement signal containing a signal error. This is because the signal error causes other coefficients to be ascertained for the predetermined model during the analysis of this measurement window, with the result that the respective measurement tuple arising therefrom is arranged at a greater distance from the noise tuple. The respective distance between a measurement tuple and a noise tuple means that those measurement windows that represent a signal error of the measurement signal can thus be determined very effectively from the plurality of measurement windows as error signal windows.

Based on the preceding explanations, the processor unit therefore has provision for the processor unit to be configured to ascertain a distance of the associated measurement tuple from the noise tuple for each measurement window and to determine from the plurality of measurement windows those measurement windows whose associated measurement tuple is at a respective distance from the noise tuple that is greater than a first, predetermined limit value as error signal windows. This ensures that each error signal window represents a portion of the measurement signal containing a signal error. Consequently, each error signal window also represents a signal error of the measurement signal.

The last-mentioned configuration of the processor unit to determine the error signal windows allows the error signal windows in which signal errors can be expected to be determined quickly and solidly. These error signal windows can be further evaluated for further analysis. A further analysis can be used to determine in particular the type and the quality of the signal errors and/or the type and/or quality of the faults that occurred during the power transmission by means of the electrical equipment. The processor unit can be configured accordingly for this purpose.

The configuration of the processor unit also affords the advantage that manual analysis of the entire measurement signal can be dispensed with. Rather, the configuration of the processor unit allows further upgrading to be able to be concentrated on specific sections, namely the error signal windows of the measurement signal. The overall effort for fault detection and/or analysis during the power transmission can be reduced to a fraction as a result.

It was already explained above that the processor unit is configured to assign each sample of the measurement signal a respective signal window. This creates a plurality of signal windows. It is also said that this results in a sequence of signal windows that moves concomitantly from sample to sample. Each signal window can include at least 16, at least 32 or at least 64 samples, for example. Each signal window preferably has 128 samples, for example. The initial phase can be very short. The processor unit can preferably be designed to execute an examination phase after each initialization phase. The number of measurement windows can be significantly greater than the number of initialization windows. For example, the number of measurement windows can be at least ten times the number of initialization windows. The processor unit can also be configured to execute the initialization phase at least 2 times per second. The number of measurement windows can be determined according to the sampling rate. The number of repetition of the initialization phase can also be increased. As such, the processor unit can be configured to execute the initialization phase 2 to 10 times per second, for example. An appropriate adjustment to the number of measurement windows can be made for this purpose. In addition, it was explained above that the noise tuple can be arranged in the center between the initial coefficient tuples. The noise tuple can thus be situated in the noise center of a “cloud” of initial coefficient tuples of the noise windows. The sampling rate for the samples of the measurement signal is preferably chosen in such a way that preferably at least 10 000 signal windows are determined as measurement windows in the examination phase. Preferably, there can also be significantly more.

It was also explained above that the processor unit is configured to ascertain a distance of the associated measurement tuple from the noise tuple for each measurement window. The distance between a respective measurement tuple and the noise tuple is preferably the Mahalanobis distance between the respective measurement tuple and the noise tuple. In regard to the ascertainment of the Mahalanobis distance, reference is made to the following publication: N-Dimensional cumulative function, and other useful facts about gaussians and normal densities by Michael Bensimhoun (Jerusalem, 06/2009).

The predetermined Xth-order model can be a linear model and/or an LPC model of corresponding order. The coefficients associated with the Xth-order model can be, for example, α-coefficients, PARCOR coefficients, or prediction error coefficients and/or normalized errors.

It was also explained above that the processor unit is configured to determine in each case one measurement window from the plurality of measurement windows as the error signal window whenever the associated measurement tuple is at a distance from the noise tuple that is greater than a first, predetermined limit value. This limit value can be, for example, one to five times a standard deviation from the expected value, or noise tuple. The predetermined limit value can be predetermined on the basis of knowledge in the art and prior testing, for example. Other options for predetermining the limit value are also possible.

An advantageous embodiment of the device is distinguished in that the processor unit is configured to determine for each initialization window the associated number of zero crossings in the portion of the measurement signal that is represented by the respective initialization window. In addition, the processor unit is preferably configured in such a way as to determine from the initialization windows the number of K initialization windows containing the most zero crossings as the noise windows. In practice it has been found that a high number of zero crossings for a portion of the measurement signal that is represented by an initialization window then indicates that this portion of the measurement signal is very noisy. In order to ascertain the noise windows containing the most noise among the initialization windows, ascertaining the number of zero crossings for the initialization windows has proven to be an efficient method. A zero crossing for a measurement signal is preferably present when the value of the measurement signal reaches or passes through the value zero or another predetermined signal value, preferably for a short time. The number K of noise windows is preferably less, in particular significantly less, than the number M of initialization windows. For example, the number K can be at most two thirds, at most half or at most one third of the number M. This allows particularly robust definition of which of the initialization windows are determined as noise windows by the processor unit. These noise windows are used in the initialization phase to ascertain a corresponding number of K initial coefficient tuples and from these the noise tuple. It is well known that noise does not permit meaningful correlation. Therefore, the use of the zero crossings and the robust definition of the noise windows is an efficient and at the same time robust way of defining the noise tuple, with the result that a distance of the associated measurement tuple from the noise tuple can be ascertained for each measurement window in the examination phase. This in turn allows the error signal windows to be defined. In addition, the possibility of determining the noise windows by ascertaining the zero crossings provides for the noise windows to be able to be ascertained in real time, or simultaneously, during the initialization phase and/or before the beginning of the examination phase.

A further advantageous embodiment of the device is distinguished in that the processor unit is configured to ascertain for each initialization window an associated signal energy in the portion of the measurement signal that is represented by the respective initialization window, wherein the processor unit is also configured to determine from the initialization windows the number of K initialization windows containing the lowest signal energies as the noise windows. This is because in practice it was also found that a low signal energy for a portion of the measurement signal that is represented by an initialization window then indicates that this portion of the measurement signal is very noisy. In order to ascertain the noise windows containing the most noise among the initialization windows, ascertaining the lowest signal energy for the initialization windows has proven to be a likewise efficient method. Thus, the noise windows can also be determined using the signal energies instead of using the zero crossings. This also allows particularly robust definition of which of the initialization windows are determined as noise windows by the processor unit. These noise windows are used in the initialization phase to ascertain a corresponding number of K initial coefficient tuples and from these the noise tuple. It is well known that noise does not permit meaningful correlation. Therefore, the use of the lowest signal energy and the robust definition of the noise windows is an efficient and at the same time robust way of defining the noise tuple, with the result that a distance of the associated measurement tuple from the noise tuple can be ascertained for each measurement window in the examination phase. This in turn allows the error signal windows to be defined. In addition, the possibility of determining the noise windows by ascertaining the lowest signal energy provides for the noise windows to be able to be ascertained in real time, or simultaneously, during the initialization phase and/or before the beginning of the examination phase.

Instead of the signal energy, the so-called “spectral flatness” can also be used. The processor unit can be configured accordingly for this purpose.

A further advantageous embodiment of the device is distinguished in that the Xth-order model is in the form of an Xth-order LPC model. LPC models are known fundamentally from the prior art. The LPC model can be described, for example, by means of the following recursion equation:

y(k)=e(k)+Σ₁^{N} aᵢ·y(k−i).

Here, k is a discrete time variable, that is to say a natural number greater than zero, y(k) is the value of the discrete measurement signal at the discrete time k and N is an order of the approximation, N being equivalent to the value X of the Xth order of the LPC model. The aᵢ are preferably the so-called linear predictors of the Nth order and e(k) is a prediction error. The predictors aᵢ preferably form the coefficients of the LPC model. Since the values of the discrete measurement signal are known, the predictors, or the coefficients, of the model can be determined by means of the processor unit in such a way that the total quadratic error of the approximation of the model in terms of the discrete measurement signal is minimized. The portion of the measurement signal represented by the respective window is taken into account in each case. The total quadratic error of each can be indicated by Q according to the following equation:

Q=Σ₁^{N} e²(k)=Σ₁^{N}(y(k)−Σ₁^{N} aᵢ·y(k−i))².

To this end, the total quadratic error of the predictors aᵢ, or coefficients, can be differentiated, the respective result equated with zero and the resulting system of equations from N linear equations solved. To this end, the processor unit can be appropriately configured in order to ascertain the coefficients of the LPC model. In respect of the LPC model and the ascertainment of the coefficients, reference is also made to the publication DE 10 2018 126 743 B3.

The Xth-order model is indeed preferably in the form of an Xth-order LPC model. However, there can also be provision for the Xth-order model to be in the form of another Xth-order mathematical model. For example, the model can be formed using a Fourier transformation or a wavelet transformation.

A further advantageous embodiment of the device is distinguished in that M is an integer of at least 100, preferably at least 10 000. In addition, there is preferably provision for K to be an integer that is preferably less than M. K is preferably less than 0.5 times M; K is preferably at most 0.1 times M. This allows robust and simple determination of the number of noise windows to be ensured.

A further advantageous embodiment of the device is distinguished in that each initialization phase lasts a maximum of 0.1 seconds, preferably a maximum of 0.05 seconds. The examination phase can last for example several seconds or even several minutes or even longer. Due to the short duration of the initialization phase, it is possible to switch to the examination phase particularly quickly. When the device is used by a user, the user will not usually notice the initialization phase.

A further advantageous embodiment of the device is distinguished in that the processor unit is configured to analyze each error signal window by means of a predetermined Nth-order model and to ascertain the associated coefficients that form a fault tuple assigned to the respective error signal window, N being an integer of at least 6, preferably 8. The analyzing can take place during the examination phase. The Nth-order model is preferably of the same type as the Xth-order model. Both models, that is to say both the Nth-order model and the Xth-order model, can each be formed by an LPC model of the corresponding order. The Xth-order model is preferably a second-order model or a third-order model. The Nth-order model is preferably a sixth-order model or an even higher-order model, such as an eighth-order model. However, the order can also be even greater. N is preferably at least 10, 12 or 14. In the examination phase, the processor unit is used to determine from the plurality of measurement windows those measurement windows whose associated measurement tuple is at a distance from the noise tuple that is greater than the first, predetermined limit value a respective error signal window. As a result, it can be assumed that the portion of the measurement signal that is represented by the respective error signal window includes a signal error. According to the last-mentioned advantageous embodiment of the device, the processor unit is configured to analyze the error signal window by means of the predetermined Nth-order model, that is to say an at least sixth-order model. The associated coefficients are ascertained by way of the analysis. The analysis can therefore be carried out in such a way as to determine the coefficients of the at least sixth-order model. As a result, the portion of the measurement signal that is represented by the error signal window can be examined particularly exactly. However, this causes not inconsiderable computation complexity for analyzing the error signal window by means of the predetermined Nth-order model. Since only a limited number of error signal windows are determined, however, this is often possible promptly and during the examination phase. In other words, only the error signal windows are analyzed more intensively. The coefficients can preferably be used to ascertain the real and imaginary parts of the poles of the portion of the measurement signal that is represented by the respective error signal window by means of the processor unit. The processor unit can be configured for this. The real and imaginary parts can be used to ascertain whether the portion of the measurement signal that is represented by the respective error signal window is due to a fault, in particular a partial discharge. By adjusting the first, predetermined limit value, it is often possible in practice to ensure that the error signal windows exclusively or largely represent portions of the measurement signal that include signal components caused by faults, and in particular partial discharges. However, in order to keep the computation complexity for the analysis of the error signal windows at an acceptable level, there can be provision for the Nth order of the model to be limited. For example, N can be a maximum of 20 or 30.

A further advantageous embodiment of the device is distinguished in that the processor unit is configured to divide the fault tuples into multiple fault groups, with the result that the fault tuples in the same fault group are each at an interval from one another that is less than a second, predetermined limit value, with the result that all error signal windows that are assigned to the same respective fault group by way of their associated fault tuples represent the same signal error. A fault in the power transmission system in electrical equipment can lead to an error signal in the detected measurement signal. Multiple error signal windows can therefore represent multiple error signals caused by the same fault during the power transmission by means of the electrical equipment. If, for example, an undesirable partial discharge takes place during the electric power transmission by means of the electrical equipment, multiple error signal windows can represent portions of the measurement signal that are heavily influenced by the partial discharge. This often means that the fault tuples ascertained by means of the processor unit on the basis of these error signal windows are characterized by the same fault origin, namely the partial discharge. There is therefore provision for these fault tuples to be assigned to the same fault group. It was found that such fault tuples are at only a short interval from each other. The maximum interval between the fault tuples can therefore be determined by the second, predetermined limit value. The processor unit is therefore preferably configured to divide the fault tuples into multiple fault groups, with the result that the fault tuples in the same fault group are each at an interval from one another that is less than the second, predetermined limit value. There can also be provision for the fault tuples in the same fault group to be arranged at least essentially at the same distance from the noise tuple. The deviation of the distances of the fault tuples from the noise tuple is preferably less than the second, predetermined limit value. This can ensure that the fault tuples in the same fault group represent the same signal error. They can therefore be caused by the same fault during the power transmission by means of the electrical equipment. The fault group can also be referred to as a so-called cluster. The number of different fault groups preferably indicates the number of different faults during the power transmission by means of the electrical equipment. If, for example, three partial discharges occur during the electric power transmission by means of the electrical equipment, the first and second predetermined limit values can be predetermined and/or selected in such a way that three fault groups are produced by the processor unit, each fault group having multiple fault tuples, each of which has the same partial discharge fault as the cause.

By dividing the fault tuples into the fault groups, the number of faults, in particular partial discharge faults, during power transmission can be identified particularly easily and quickly. In addition, the fault tuples and the associated error signal windows can be used to perform a quick and precise analysis as to where and with what intensity the partial discharge took place.

A further advantageous embodiment of the device is distinguished in that the processor unit is configured to divide the fault signal windows into multiple fault groups, with the result that the fault tuples of the error signal windows in the same fault group are each at an interval from one another that is less than a second, predetermined limit value, with the result that all error signal windows in the same respective fault group represent the same signal error. This embodiment is similar to the previous embodiment of the device. However, instead of grouping the fault tuples, here the error signal windows are grouped. Reference is therefore made to the previous, preferred explanations, advantageous features, technical effects and/or advantages in an analogous manner for this embodiment of the device.

A further advantageous embodiment of the device is distinguished in that the processor unit is configured to ascertain a number of different faults in the equipment on the basis of the number of fault groups. If, for example, the fault tuples are divided into three fault groups or the error signal windows are divided into three fault groups by means of the processor unit, the processor unit can deduce the applicable number of the different faults on the basis of this number of fault groups. This is because the number of faults preferably corresponds to the number of fault groups.

A further advantageous embodiment of the device is distinguished in that the processor unit is configured to generate an image signal that represents the measurement signal as a signal graph, and wherein the processor unit is configured to index the portions of the signal graph that are based on samples of the measurement signal that are assigned to error signal windows in the same fault group in the same visual manner. Even though reference is made in this context to the error signal windows in the same fault group, the same can apply to the fault tuples in the same fault group, since each of the fault tuples is assigned to one of the error signal windows. For example, the portions of the signal graph that are caused by the same fault can be indexed in the same manner. If, for example, a partial discharge fault occurs during the power transmission by means of the electrical equipment, multiple error signal windows can represent this partial discharge fault by way of corresponding signal components. As explained above, these error signal windows can be assigned to the same fault group. However, it is also possible for the fault tuples assigned to the error signal windows to be assigned to the same fault group. In both cases, the fault group includes error signal windows, or error signal windows assigned by way of fault tuples, that can visually index the partial discharge fault or another fault particularly succinctly. The applicable portions of the signal graph that are determined by the same group of error signal windows (or associated tuples) are indexed in the same visual manner by means of the processor unit. This can be done, for example, using the same color (for example red, green or blue). However, it is also possible for the applicable portions of the signal graph to be indexed in the same manner using the same line dashing, line thickness and/or other features. The device can be designed to make the image signal available. For example, the device can have an output signal interface, the processor unit being configured to control the output signal interface in such a way as to transmit, in particular send, the image signal. As a result, the image signal can be transmitted to a remote unit and, if necessary, displayed there.

A further advantageous embodiment of the device is distinguished in that the device has a display unit. In addition, the processor unit can be configured to control the display unit in such a way that the display unit shows an image on the basis of the image signal, with the result that the image visually reproduces the signal graph. The signal graph visually reproduced by the image can index portions that are based on samples of the measurement signal that are assigned to error signal windows in the same fault group in the same visual manner. On the display unit, it is thus possible to see particularly quickly which portions of the signal graph are caused by the same fault, in particular the same partial discharge fault.

A further advantageous embodiment of the device is distinguished in that the processor unit is configured to execute the initialization phase repeatedly, with the result that the noise tuple is re-ascertained with each initialization phase. This allows an update to any changing noise to be achieved.

A further advantageous embodiment of the device is distinguished in that the processor unit is configured to execute at least one examination phase after each initialization phase. There is preferably provision for exactly one examination phase to be executed by means of the processor unit after each initialization phase. However, there can also be provision for the processor unit to be configured to execute multiple examination phases after each initialization phase. In this case, the examination phases can be executed by the processor unit one after the other.

According to a second aspect of the present disclosure, a system is provided for power transmission, the system having equipment for transmitting an electric power signal from a supply point of the equipment to a delivery point of the equipment. The system also has a sensor unit and a device. The device is designed according to the first aspect of the present disclosure and/or one of the associated advantageous embodiments. Reference is made to the advantageous explanations, preferred features, technical effects and/or advantages as have been explained in connection with the device according to the first aspect and/or one of the associated advantageous embodiments in an analogous manner for the device of the system. The sensor unit of the system is arranged at a connection point of the equipment between the supply point and the delivery point. The sensor unit is designed to detect the electric power signal and to generate a digital measurement signal that represents the power signal detected at the connection point. The sensor unit is coupled to the signal interface of the device in order to transmit the measurement signal to the signal interface. In respect of the advantages of the system and the technical effects of the system, reference is made to the technical effects and advantages as have already been explained in connection with the device according to the first aspect of the present disclosure and/or one of the associated advantageous embodiments. There are no repetitions.

An advantageous embodiment of the system is distinguished in that the equipment is in the form of a high-voltage line, a transformer, a rotating electrical machine, a gas-insulated line or in the form of gas-insulated switchgear. The equipment preferably has the high-voltage line, which extends from the supply point of the equipment to the delivery point of the equipment. The high-voltage line can be designed to transmit electric power using a high DC voltage or a high AC voltage. Alternatively and/or additionally, the equipment can have a transformer. If the equipment has the transformer instead of the high-voltage line, the supply point can be formed on the primary side of the transformer and the delivery point can be formed on the secondary side of the transformer. Electric power can thus be transmitted from the supply point, namely the primary side of the transformer, to the delivery point, namely the secondary side of the transformer. The aforementioned technical effects and/or advantageous embodiments apply to the further possible embodiments of the equipment in an analogous manner.

According to a third aspect of the present disclosure, a method is provided for operating a device having an input interface for receiving a digital measurement signal containing a sequence of samples, the measurement signal representing a signal detected at a connection point of electrical equipment. The method comprises at least the following step: a) using the processor unit to assign each sample of the measurement signal a respective signal window formed from a respective portion of the sequence of samples of the measurement signal containing the respective sample and a predetermined number of temporally preceding samples of the measurement signal. The method is designed to carry out the following steps in an initialization phase by means of the processor unit: b) determining a number of M signal windows as initialization windows, c) determining from the M initialization windows a number of K initialization windows as noise windows, d) analyzing each noise window by means of a predetermined Xth-order model and ascertaining the associated coefficients that form an initial coefficient tuple assigned to the respective noise window, X being an even number between one and five, and e) ascertaining an expected value as a noise tuple from the initial coefficient tuples of the noise windows. In addition, the method is designed to carry out the following steps in an examination phase by means of the processor unit: f) determining a plurality of the signal windows as measurement windows, g) analyzing each measurement window by means of the predetermined Xth-order model and ascertaining the associated coefficients that form a measurement tuple assigned to the respective measurement window, h) ascertaining a distance of the associated measurement tuple from the noise tuple for each measurement window, and i) determining from the plurality of measurement windows the measurement windows whose associated measurement tuple is at a respective distance from the noise tuple that is greater than a first, predetermined limit value as error signal windows, with the result that each error signal window represents a signal error of the measurement signal.

The method corresponds at least essentially to the device according to the first aspect of the present disclosure. Reference is therefore made to the advantageous explanations, preferred features, advantages and/or technical effects as have been explained for the device according to the first aspect of the present disclosure and/or the associated advantageous embodiments at least in an analogous manner for the method. There is no repetition.

An advantageous embodiment of the method is distinguished in that the initialization phase is executed repeatedly by the processor unit, preferably 2 to 10 times per second. The repeated execution of the initialization phase allows the noise tuple to be regularly updated in order to thus allow the most precise possible distinction between the noise component of the measurement signal and the error component of the measurement signal. The method is preferably also distinguished in that at least one examination phase is executed by means of the processor unit after each initialization phase.

A further advantageous embodiment of the method is distinguished in that the Xth-order model is formed by an Xth-order LPC model. In this context too, reference is made to the applicable advantageous explanations, preferred features, effects and/or advantages as have already been explained for the corresponding advantageous embodiment of the device according to the first aspect of the present disclosure.

A further advantageous embodiment of the method is distinguished in that step c) comprises the following substeps c.1) and c.2): c.1) ascertaining for each initialization window the associated number of zero crossings in the portion of the measurement signal that is represented by the respective initialization window, and c.2) determining from the M initialization windows a number of K initialization windows containing the most zero crossings as noise windows. Each of the two substeps c.1) and c.2) are carried out by means of the processor unit. In step c.1), the number of zero crossings in the portion of the measurement signal that is represented by the respective initialization window is ascertained by means of the processor unit. And in step c.2), the number of K noise windows from the M initialization windows is determined on the basis of the number of zero crossings by means of the processor unit. For this embodiment of the method too, reference is made to the advantageous explanations, preferred features, technical effects and advantages as have already been explained above for the correspondingly advantageous embodiment of the device according to the first aspect of the present disclosure in an analogous manner. There is no repetition here either.

A further advantageous embodiment of the method is distinguished in that step c) comprises the following substeps c.1) and c.2): c.1) ascertaining for each initialization window the associated signal energy in the portion of the measurement signal that is represented by the respective initialization window, and c.2) determining from the M initialization windows a number of K initialization windows containing the lowest signal energies as noise windows. Each of the two substeps c.1) and c.2) are carried out by means of the processor unit. In step c.1), the signal energy in the portion of the measurement signal that is represented by the respective initialization window is ascertained by means of the processor unit. And in step c.2), the number of K noise windows from the M initialization windows is determined on the basis of the lowest signal energy by means of the processor unit. For this embodiment of the method too, reference is made to the advantageous explanations, preferred features, technical effects and advantages as have already been explained above for the correspondingly advantageous embodiment of the device according to the first aspect of the present disclosure in an analogous manner. There is no repetition here either.

A further advantageous embodiment of the method is distinguished in that the method is designed to also carry out the following step in the examination phase by means of the processor unit: j) analyzing each error signal window by means of a predetermined Nth-order model and ascertaining the associated coefficients that form a fault tuple assigned to the respective error signal window, N being an integer of at least six, preferably eight.

A further advantageous embodiment of the method is distinguished in that the method is designed to also carry out the following step in the examination phase by means of the processor unit: k) dividing the fault tuples into multiple fault groups, with the result that the fault tuples in the same fault group are each at an interval from one another that is less than a second, predetermined limit value, with the result that all error signal windows that are assigned to the same respective fault group by way of their associated fault tuples represent the same signal error.

For the two advantageous embodiments of the method that have just been mentioned, reference is made in each case to the advantageous explanations, preferred features, effects and/or advantages as have already been mentioned above for the two corresponding advantageous embodiments of the device according to the first aspect of the present disclosure in an analogous manner.

Further features, advantages and possible applications of the present disclosure can be found in the following description of the exemplary embodiments and in the figures. Here, all features described and/or illustrated in the figures form the subject matter of the present disclosure alone and in any desired combination even irrespective of their composition in the individual claims or their dependency references. In the figures, the same reference signs continue to stand for the same or similar objects.

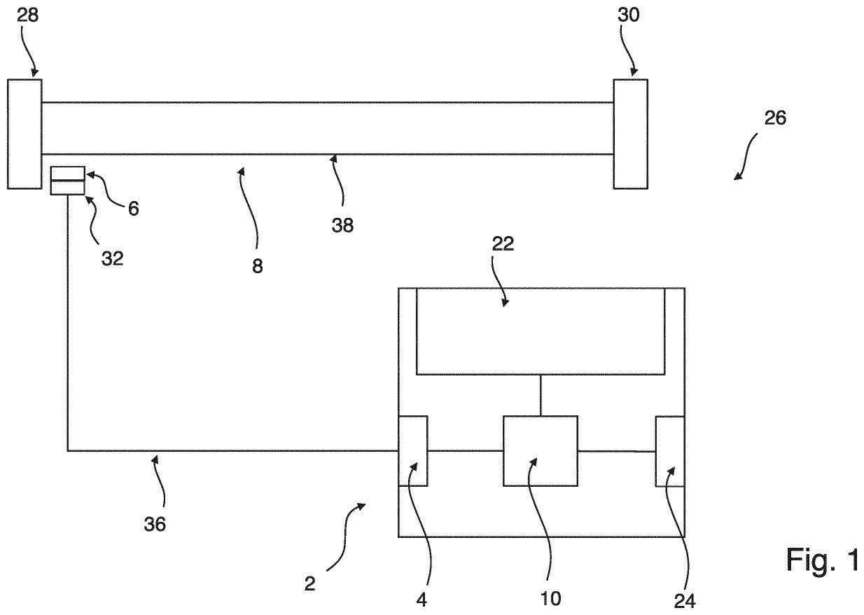

FIG. 1 shows an advantageous embodiment of the device and the system in a schematic representation.

FIG. 1 schematically shows an advantageous embodiment of the device 2. The device 2 has an input signal interface 4 and a processor unit (processor) 10. In addition, the device 2 can have a display unit (display) 22. There is preferably provision for the device 2 to have an output signal interface 24.

FIG. 1 also schematically shows electrical equipment 8. The electrical equipment 8 is used to transmit electric power. For example, the electrical equipment 8 can be designed for high-voltage direct current transmission. However, it is also possible for the electrical equipment 8 to be designed in a different way for the transmission of electric power. For example, the electrical equipment 8 can be designed for high-voltage alternating current transmission. The electrical equipment 8 preferably has a supply interface 28 and a delivery interface 30. At least one electrical line 38 can extend from the supply interface 28 to the delivery interface 30. A flow of current can be produced via the electrical line 38. However, the advantageous embodiment of the electrical equipment 8 shown in FIG. 1 should be understood only by way of illustration. As such, in an alternative embodiment, the electrical equipment 8 can be formed by a transformer, the primary-side connection of which forms the supply interface 28 and the secondary-side connection of which forms the delivery interface 30.

The electrical equipment 8 and the device 2 can form a part of a system 26. For the system 26, there can also be provision for the system 26 to have a sensor unit (sensor) 32, which is preferably coupled to the input signal interface 4 of the device 2 via a signal line 36. The sensor unit 32 can be arranged at a connection point 6 of the electrical equipment 8 in order to electrically detect the power transmission. For example, the sensor unit 32 can be designed to detect a voltage and/or to detect an electrical current through the electrical line 38. The sensor unit 32 is thus designed to detect an electric power signal of the electrical equipment 8. The sensor unit 32 is also designed to generate an analog measurement signal that represents the power signal detected at the connection point 6. The measurement signal can be transmitted from the sensor unit 32 to the input signal interface 4 of the device 2 by means of the signal line 36. There it is digitized by the processor unit 10. The digital measurement signal is a sequence of samples of the detected signal. The input signal interface 4 of the device 2 is designed to receive the digital measurement signal containing the associated sequence of samples.

The explanations of the device 2 above and below can preferably relate to the device 2 alone. However, there is also provision for the same explanations pertaining to the device 2 to apply in an analogous manner to the system 26, since the system 26 can include the device 2. The same can apply conversely.

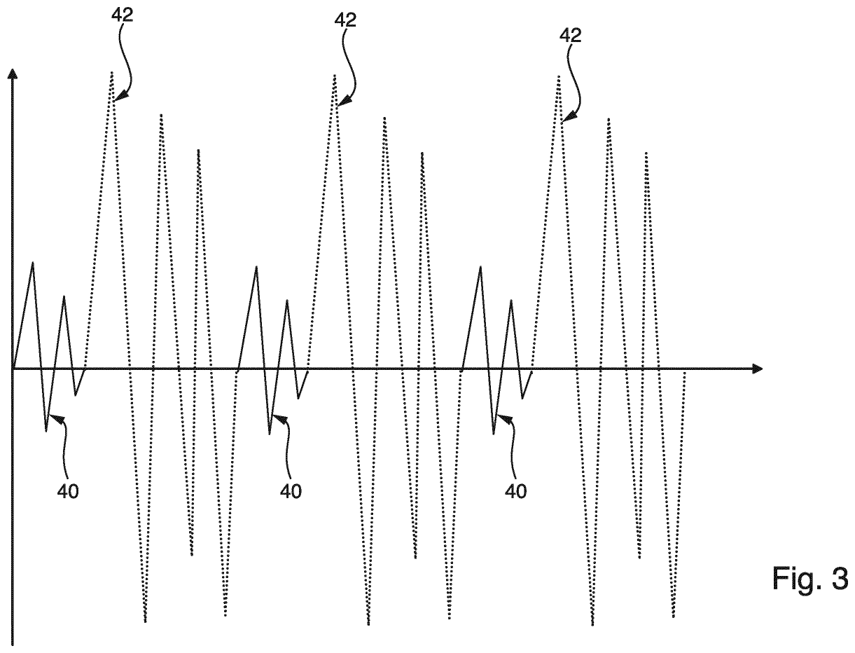

FIG. 3 schematically shows an illustrative detail from a measurement signal plotted over time. In principle, at least a portion of the measurement signal represents the power signal detected at the connection point 6 of the electrical equipment 8. However, if a fault occurs, for example a partial discharge in the electrical line 38, this fault, in particular the partial discharge, causes an associated signal component in the measurement signal. The difficulty here is establishing which portions of the measurement signal include a signal component that represent the respective fault particularly succinctly.

The device 2 therefore at least also serves the purpose of ascertaining error signal windows of the measurement signal, each error signal window representing a signal error of the measurement signal. The error signal windows can represent different signal errors. However, it is also possible for at least multiple error signal windows to represent the same signal error of the measurement signal. This is the case particularly when these signal errors are caused by the same fault, such as a partial discharge. Each error signal can thus be a portion of the component of the measurement signal that is present as a result of a fault, in particular a partial discharge, in the electrical equipment 8 during power transmission.

In order to ensure the desired purpose of the device 2, there is provision for an advantageous configuration of the processor unit 10, which will be explained below.

The processor unit 10 is configured to assign each sample of the measurement signal a respective signal window formed from a respective portion of the sequence of samples of the measurement signal containing the respective sample and a predetermined number of temporally preceding samples of the measurement signal. Each signal window can include the same number of samples of the measurement signal. For example, there can be provision for each signal window to include 32, 64 or 128 samples of the measurement signal. The samples in a signal window are a portion of the sequence of the samples of the measurement signal. The samples in the respective signal window are therefore samples that are directly successive in time. If the processor unit 10 generates a signal window for a sample of the measurement signal, for example, and assigns it to the respective sample, this signal window includes the respective sample of the measurement signal and a predetermined number of temporally preceding samples, for example 127 temporally preceding samples, for the respective sample of the measurement signal. In total, the signal window in this example includes 128 samples. Since each sample of the measurement signal has an assigned signal window, it is also said that the accordingly produced signal windows are a moving sequence of signal windows. When the initialization phase 12 and the examination phase 18 are explained below, it should be taken into account that the signal windows continue to be assigned to each sample of the measurement signal, and in particular simultaneously.

The processor unit 10 is configured to carry out multiple steps in an initialization phase 12, which will be explained below. Thus, the processor unit 10 is configured to determine a number of M signal windows as the initialization window during the initialization phase 12. This is a portion of the signal windows that are continuously assigned to the samples of the measurement signal by means of the processor unit 10. The number M is an integer between 100 and 50 000. The number M is preferably an integer between 1000 and 10 000. Thus, for example 10 000 initialization windows can be determined by means of the processor unit 10 in the initialization phase 12. A number of K noise windows is determined from these initialization windows. The number K is less than the number M. Thus, the number K can be an integer and preferably less than 0.5 or 0.1 times the number M. By way of illustration, it is assumed that the number K is 1000. Thus, for example 1000 noise windows can be determined from the set of initialization windows by means of the processor unit 10. Which of the initialization windows are determined as noise windows can be established by ascertaining the number of zero crossings or by ascertaining the signal energy in the portions of the measurement signal that are represented by the initialization windows. For this purpose, the processor unit can be configured to ascertain for each initialization window the associated number of zero crossings or the associated signal energy in the portion of the measurement signal that is represented by the respective initialization window. Each initialization window thus has an assigned number of zero crossings or an assigned specific signal energy. The number of zero crossings or the specific signal energy in the initialization windows usually differs. Those initialization windows that each have the greatest assigned number of zero crossings or the lowest assigned signal energy represent the portions of the measurement signal containing the highest proportion of noise. The processor unit 10 is therefore configured to determine from the M initialization windows those initialization windows containing the most zero crossings or containing the lowest signal energy as the noise windows. The noise windows thus form a subset of all initialization windows, the portions of the measurement signal that are represented by the noise windows being characterized by a large noise component.

An Xth-order model can be stored by the processor unit 10, and in particular by an associated memory unit. The model is preferably a mathematical model designed to model the power transmission by means of the equipment 8. The model may comprise coefficients in order to adjust a transfer function, or a transmission distance, represented by the model. By adjusting the coefficients of the model, it is thus possible to achieve a particularly good approximation of the actual transfer function during the power transmission by means of the equipment 8 on the basis of the selected coefficients. The model is also referred to as the predetermined model. The processor unit 10 is configured so as, in the initialization phase 12, to analyze each noise window by means of the predetermined Xth-order model and thereby to ascertain the associated coefficients. An associated set of coefficients is thus ascertained for each noise window. The coefficients can differ from noise window to noise window. In order to achieve fast ascertainment, it has proven to be advantageous if X is an even number between one and five. For example, X can be the number two. In this case, the predetermined model would be a second-order model. The number of coefficients preferably corresponds to the order of the model. In the previous example, there would thus be provision for two coefficients for the second-order model. The coefficients ascertained for a noise window by means of the processor unit 10 each form an initial coefficient tuple 14 assigned to the respective noise window. The noise can differ from noise window to noise window, with the result that the initial coefficient tuples 14 can also differ from noise window to noise window. The processor unit 10 is therefore configured to ascertain an expected value as a noise tuple 16 from the initial coefficient tuple 14 of the noise windows in the initialization phase 12. The noise tuple 16 can thus be the arithmetic mean of the K initial coefficient tuples 14. If each initial coefficient tuple 14 consists of two coefficients and if for example 1000 noise windows and thus 1000 initial coefficient tuples 14 are ascertained, the noise tuple 16 can represent an expected value for the initial coefficient tuples 14. To put it simply, the noise tuple 16 can be arranged in the “noise center”. If another signal window is now analyzed as the initialization window by means of the predetermined model and the associated coefficients are ascertained, the distance between the noise tuple 16 and the applicable tuple comprising the coefficients can be taken as a basis for ascertaining whether the applicable signal window should be rated as noise or, if the interval is great enough, the signal window represents a portion of the measurement signal containing a signal error.

The processor unit 10 is configured to carry out multiple steps in the examination phase 18, which are explained below. The processor unit 10 is thus configured to determine a plurality of signal windows as measurement windows in the examination phase 18. There is preferably provision for the measurement windows to differ from the initialization windows. For example, those signal windows that follow the last initialization window can be determined as measurement windows. The number of measurement windows is preferably significantly greater than the number of initialization windows. For example at least 10 000 signal windows can be determined as measurement windows in the examination phase 18. However, significantly more are preferred, for example 20 000, 30 000 or 100 000. The processor unit 10 is also configured to analyze each measurement window by means of the predetermined Xth-order model and thereby determine the associated coefficients. This is the same Xth-order model as was also already used in the initialization phase 12. Associated coefficients are thus ascertained for each measurement window, said coefficients forming a measurement tuple 20 assigned to the respective measurement window. There is thus provision for a measurement tuple 20 comprising the respective coefficients for each measurement window.

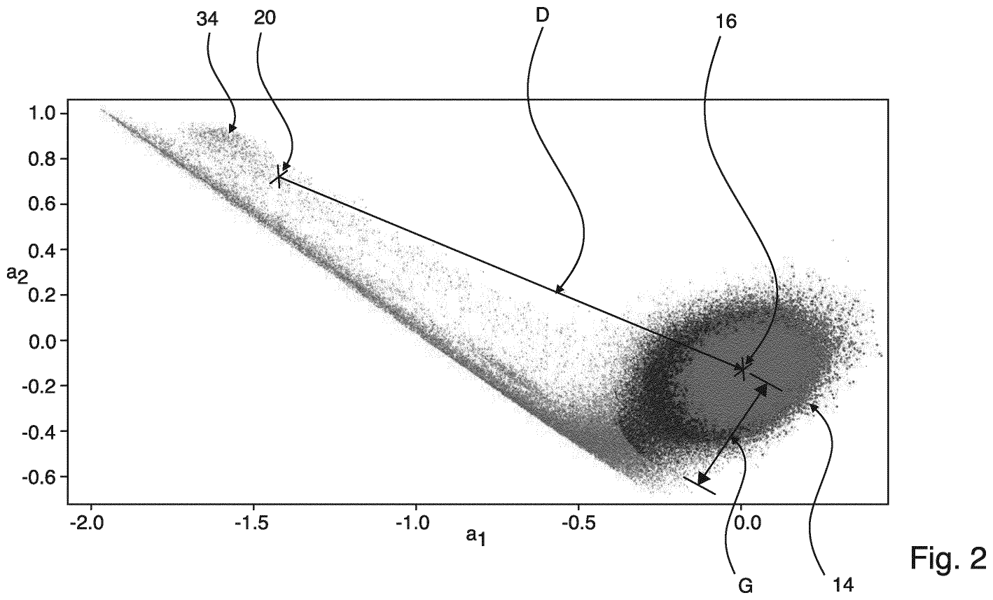

FIG. 2 schematically shows a plurality of coefficient tuples 34 by way of corresponding dots. Each coefficient tuple 34 consists of coefficients that have been ascertained during the analysis of a signal window by means of the Xth-order model. This analysis takes place in terms of the noise windows in the initialization phase 12. This results in a plurality of initial coefficient tuples 14, which are reproduced as a cloud of points in FIG. 2 owing to their number. The noise tuple 16 is arranged in the center of this cloud of initial coefficient tuples 14. The noise tuple 16 thus forms the expected value for the initial coefficient tuples 14.

In the examination phase 18, the measurement windows are analyzed using the same Xth-order model, with the result that associated coefficients form the aforementioned measurement tuples 20. One of these measurement tuples 20 is marked by a cross in FIG. 2. In order to establish whether a measurement tuple 20 indicates noise in the portion of the measurement signal that is represented by the associated measurement window, or whether the measurement tuple 20 for the respective measurement window indicates a signal error in the portion of the measurement signal that is represented by the measurement window, a predetermined, first limit value G is defined. If the distance D between the respective measurement tuple 20 and the noise tuple 16 is greater than the first limit value G, the portion of the measurement signal that is represented by the associated measurement window is regarded as a signal error that has occurred as a result of a fault during the power transmission by means of the equipment 8. However, if the distance D were less than the limit value G, this measurement tuple 20 would indicate that the portion of the measurement signal that is represented by the associated measurement window does not represent a signal error, but rather is characterized by noise.

The processor unit 10 is therefore configured so as, in the examination phase 18, to ascertain the distance D of the associated measurement tuple 20 from the noise tuple 16 for each measurement window and to determine from the plurality of measurement windows those measurement windows whose associated measurement tuple 20 is at a respective distance D from the noise tuple 16 that is greater than the first, predetermined limit value G as error signal windows. The result of this is that each of the error signal windows determined in this way represents a portion of the measurement signal that includes a signal error. This is because each of these portions of the measurement signal that are represented by the error signal windows is characterized at least in part by a fault during the power transmission by means of the equipment 8. The signal error of a measurement signal is, for example, the component of the measurement signal that is caused by the respective fault. Each error signal window therefore also represents a signal error of the measurement signal.

The error signal windows determined in the examination phase 18 represent the respectively relevant portions of the measurement signal that can be used to examine possible faults during the power transmission by means of the electrical equipment 8.

There is therefore preferably provision for the device 2 to have an output signal interface 24 that is designed to transmit an output signal. The output signal can represent the error signal windows directly or indirectly. For example, the output signal can include data for identifying the error signal windows in the measurement signal. However, there can also be provision for the output signal to represent each of the signal windows. The processor unit 10 of the device 2 can be designed to control the output signal interface 24 in such a way as to transmit, in particular to send, the output signal. The information ascertained by the device 2 about the error signal windows can be made available to other devices and/or units via the output signal.

As an alternative or in addition to the output signal interface 24, the device 2 can have a display unit 22. In addition, the processor unit 10 can be configured to generate an image signal that represents the measurement signal as a signal graph. The processing unit 10 can be configured to transmit the image signal to the display unit 22. The display unit 22 can be designed to produce an image on the display unit 22 on the basis of the image signal.

Furthermore, there is advantageously provision for the processor unit 10 to be configured to index the portions of the signal graph represented by the image signal that are based on samples of the measurement signal that are assigned to error signal windows in the same fault group in the same visual manner. The processor unit 10 can be configured to divide error signal windows into multiple fault groups. Error signal windows in the same fault group can each represent an error signal that is caused by the same fault during the power transmission by means of the electrical equipment 8.

FIG. 3 shows a detail from the measurement signal, the signal windows 40 in a first fault group being shown as a solid line and the signal windows 42 in a second fault group being shown as a dotted line. The processor unit 10 is preferably configured to control the display unit 22 in such a way that the display unit 22 displays an applicable image on the basis of the image signal, with the result that the image visually reproduces the signal graph and preferably the portions of the signal graph using the same respective indexing.

It has already been explained for the initialization phase 12 and the examination phase 18 that an Xth-order model is used for the analysis in each case. The Xth-order model is preferably an Xth-order LPC model. Alternatively, a different mathematical model can also be used. This can be formed using a Fourier transformation or a wavelet transformation, for example.

In addition, it has proven to be advantageous if each of the error signal windows is analyzed by means of a higher-order model. This higher-order model can be of the same type as the Xth-order model. There is therefore preferably provision for the processor unit 10 to be configured to analyze each error signal window by means of a predetermined Nth-order model and thereby ascertain the associated coefficients that form a fault tuple assigned to the respective error signal window, N being an integer of at least six and preferably at least eight. The Nth-order model can also be stored by the processor unit 10, and in particular an associated memory unit. In addition, there is preferably provision for the Nth-order model to be an Nth-order LPC model. As explained above, the Nth order can be at least six, at least eight, but also preferably at least ten, twelve or fourteen. The higher order of the Nth-order model affords the advantage that the error signal windows can be analyzed more exactly in order to be able to examine the respective fault more exactly. In addition, the error signal windows can be grouped on the basis of the fault tuples. For example, there is advantageously provision for the processor unit 10 to be configured to divide the fault tuples into multiple fault groups, with the result that the fault tuples in the same fault group are each at an interval from one another that is less than a second, predetermined limit value G. All error signal windows assigned to the same respective fault group by way of their associated fault tuples can therefore represent the same or an at least similar signal error. Each of these signal errors can be caused by the same fault during the power transmission by means of the electrical equipment 8. Fault tuples and/or error signal windows that have the same fault origin, in particular caused by the same partial discharge, can thus be assigned to the same fault group. The number of groups can therefore correspond to the number of different faults during the power transmission by means of the electrical equipment 8.

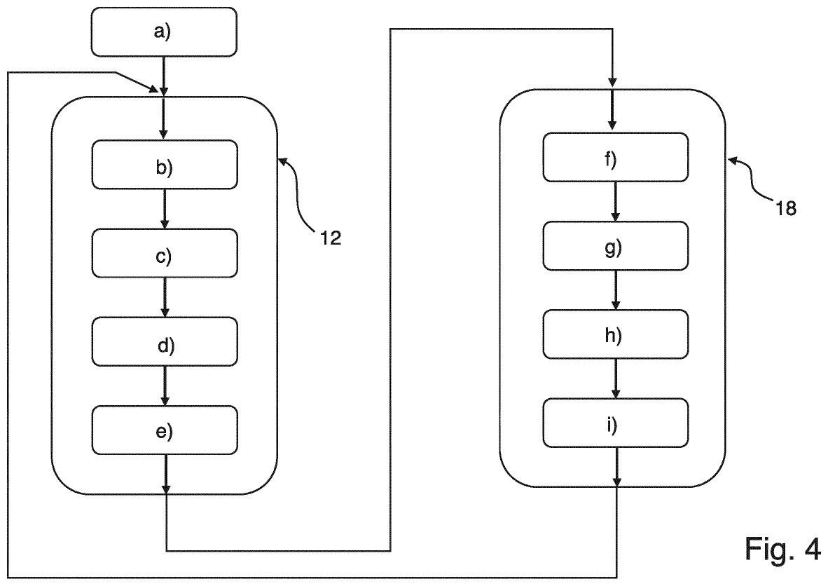

FIG. 4 shows an advantageous embodiment of the method. The method comprises the method steps a) to i). According to method step a) the processor unit 10 is used to assign each sample of the measurement signal a respective signal window formed from a respective portion of the sequence of samples of the measurement signal containing the respective sample and a predetermined number of temporally preceding samples of the measurement signal. Step a) is carried out continuously, and also preferably at the same time as the initialization phase 12 and/or the examination phase 18.

Method steps b) to e) are assigned to the initialization phase 12. The method is designed to carry out the following steps in the initialization phase 12 by means of the processor unit 10: b) determining a number of M signal windows as initialization windows, c) determining from the M initialization windows a number of K initialization windows as noise windows, d) analyzing each noise window by means of a predetermined Xth-order model and ascertaining the associated coefficients that form an initial coefficient tuple assigned to the respective noise window, X being an even number between one and five, and e) ascertaining an expected value as a noise tuple from the initial coefficient tuples of the noise windows.

In addition, the method is designed to carry out the following steps in the examination phase 18 by means of the processor unit 10: f) determining a plurality of the signal windows as measurement windows, g) analyzing each measurement window by means of the predetermined Xth-order model and ascertaining the associated coefficients that form a measurement tuple assigned to the respective measurement window, h) ascertaining a distance of the associated measurement tuple from the noise tuple for each measurement window, and i) determining from the plurality of measurement windows the measurement windows whose associated measurement tuple is at a respective distance from the noise tuple that is greater than a first, predetermined limit value as error signal windows, with the result that each error signal window represents a signal error of the measurement signal.

As can be seen from FIG. 4, the examination phase 18 follows the initialization phase 12. Steps b) to e) are thus carried out in the initialization phase 12 by means of the processor unit 10. Steps f) to i) are then carried out in the examination phase 18. The initialization phase 12 can then begin again. In principle, however, it is also possible for the examination phase 18 to be executed repeatedly after the initialization phase 12 before a new initialization phase 12 is started again. For the method, reference is made to the preceding, preferred explanations, advantageous features, technical effects and/or advantages in an analogous manner.

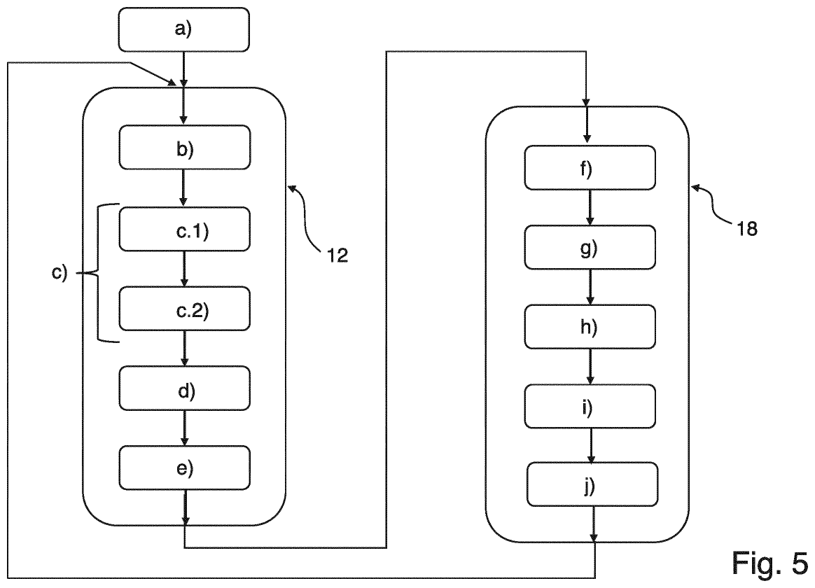

FIG. 5 shows a further advantageous embodiment of the method, reference being made to the explanations relating to the previous steps a) to i). In step c), the method from FIG. 5 comprises the substeps c.1) and c.2), which are carried out by the processor unit 10: c.1) for each initialization window, the associated number of zero crossings and/or an associated signal energy in the portion of the measurement signal that is represented by the respective initialization window is ascertained, and c.2) a number of K initialization windows containing the most zero crossings and/or containing the lowest signal energy are determined from the M initialization windows as noise windows.

In addition, the method shown in FIG. 5 also includes step j) of the examination phase 18, which is carried out by means of the processor unit 10. According to step j), each error signal window is analyzed by means of a predetermined Nth-order model and the associated coefficients that form a fault tuple assigned to the respective error signal window are ascertained, N being an integer of at least 6, preferably 8.

In addition, it should be pointed out that “having” does not exclude any other elements or steps and “a” or “an” does not exclude a plurality. Furthermore, it should be pointed out that features that have been described with reference to one of the above exemplary embodiments can also be used in combination with other features of other exemplary embodiments described above. Reference signs in the claims should not be construed as a limitation.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

a1 first coefficient

a2 second coefficient

D distance

G limit value

2 device

4 input signal interface

6 connection point

8 equipment

10 processor unit

12 initialization phase

14 initial coefficient tuple

16 noise tuple

18 examination phase

20 measurement tuple

22 display unit

24 output signal interface

26 system

28 supply interface

30 delivery interface

32 sensor unit

34 coefficient tuple

36 signal line

38 electrical line

40 signal window of a first fault group

42 signal window of a second fault group

1. A device, the device comprising:
an input signal interface configured to receive a digital measurement signal, containing a sequence of samples, that represents a signal detected at a connection point of electrical equipment, and
a processor,
wherein the processor is configured to assign each sample of the measurement signal a respective signal window formed from a respective portion of the sequence of samples of the measurement signal containing the respective sample and a predetermined number of temporally preceding samples of the measurement signal;
wherein the processor is further configured so as, in an initialization phase, to determine a number of M signal windows as initialization windows and, from the M initialization windows, to determine a number of K noise windows, to analyze each of the K noise windows using a predetermined Xth-order models and to ascertain the associated coefficients that form an initial coefficient tuple assigned to the respective noise window of the K noise windows, and to ascertain an expected value as a noise tuple from the initial coefficient tuples of the K noise windows, X being an even number between one and five; and
wherein the processor unit is further configured so as, in an examination phase to determine a plurality of the M signal windows as measurement windows, to analyze each of the measurement windows using the predetermined Xth-order model, and to ascertain the associated coefficients that form a measurement tuple assigned to each of the respective measurement windows, to ascertain a distance of the associated measurement tuple from the noise tuple for each of the measurement windows, and to determine, from the plurality of measurement windows, the measurement windows whose associated measurement tuple is at a respective distance from the noise tuple that is greater than a first, predetermined limit value G as error signal windows, with the result that each error signal window represents a signal error of the measurement signal.

2. The device as claimed in claim 1,
wherein the processor is further configured to ascertain for each initialization window the associated number of zero crossings and/or the associated signal energy in the portion of the measurement signal that is represented by the respective initialization window, and
wherein the processor is further configured to determine from the initialization windows the number of K initialization windows containing the most zero crossings and/or containing the lowest signal energy as the noise windows.

3. The device as claimed in claim 1, wherein the Xth-order model is in the form of an Xth-order LPC model.

4. The device as claimed in claim 1, wherein M is an integer of at least 100, and wherein K is an integer that is less than M.

5. The device as claimed in claim 1, wherein each initialization phase lasts a maximum of 0.1 seconds.

6. The device as claimed in claim 1, wherein the processor is further configured to analyze each error signal window using a predetermined Nth-order model and to ascertain the associated coefficients that form a fault tuple assigned to the respective error signal window, N being an integer of at least 6.

7. The device as claimed in claim 1, wherein the processor is further configured to divide the fault tuples into multiple fault groups, with the result that the fault tuples in the same fault group are each at an interval from one another that is less than a second, predetermined limit value G, with the result that all error signal windows that are assigned to the same respective fault group by way of their associated fault tuples represent the same signal error.

8. The device as claimed in claim 1, wherein the processor is further configured to divide the error signal windows into multiple fault groups, with the result that the fault tuples of the error signal windows in the same fault group are each at an interval from one another that is less than a second, predetermined limit value G, with the result that all error signal windows in the same respective fault group represent the same signal error.

9. The device as claimed in claim 7, wherein the processor is further configured to ascertain a number of different faults in the equipment on the basis of the number of fault groups.

10. The device as claimed in claim 7,
wherein the processor is further configured to generate an image signal that represents the measurement signal as a signal graph, and
wherein the processor is further configured to index the portions of the signal graph that are based on samples of the measurement signal that are assigned to error signal windows in the same fault group in the same visual manner.

11. The device as claimed in claim 1 wherein the device further comprises a display, wherein the processor is further configured to control the display in such a way that the display shows an image on the basis of the image signal, with the result that the image visually reproduces the signal graph.

12. The device as claimed in claim 1, wherein the processor is further configured to execute the initialization phase repeatedly, with the result that the noise tuple is re-ascertained with each initialization phase.

13. The device as claimed in claim 1, wherein the processor is further configured to execute at least one examination phase after each initialization phase.

14. A system for power transmission, the system comprising:
equipment configured to transmit an electric power signal from a supply interface of the equipment to a delivery interface of the equipment,
a sensor, and
the device as claimed in claim 1,
wherein the sensor is arranged at a connection point of the equipment between the supply interface and the delivery interface,
wherein the sensor is configured to detect the electric power signal and to generate a digital measurement signal that represents the power signal detected at the connection point, and
wherein the sensor is coupled to the signal interface of the device in order to transmit the measurement signal to the signal interface.

15. The system as claimed in the claim 14, wherein the equipment is in the form of a high-voltage line, transformer, rotating electrical machine, gas-insulated lines or gas-insulated switchgear.

16. A method for operating a device having an input signal interface for receiving a digital measurement signal, containing a sequence of samples, that represents a signal detected at a connection point of electrical equipment, the method comprising:
a) using a processor to assign each sample of the measurement signal a respective signal window formed from a respective portion of the sequence of samples of the measurement signal containing the respective sample and a predetermined number of temporally preceding samples of the measurement signal;
wherein the method further comprises carrying out in an initialization phase using the processor:
b) determining a number of M signal windows as initialization windows,
c) determining from the M initialization windows a number of K initialization windows as noise windows,
d) analyzing each of the noise windows using a predetermined Xth-order model and ascertaining the associated coefficients that form an initial coefficient tuple assigned to the respective noise window, X being an even number between one and five, and
e) ascertaining an expected value as a noise tuple from the initial coefficient tuple of the noise windows; and
wherein the method further comprises carrying out in an examination phase using the processor:
f) determining a plurality of the signal windows as measurement windows,
g) analyzing each measurement window using the predetermined Xth-order model and ascertaining the associated coefficients that form a measurement tuple assigned to the respective measurement window,
h) ascertaining a distance D of the associated measurement tuple from the noise tuple for each measurement window, and
i) determining from the plurality of measurement windows the measurement windows whose associated measurement tuple is at a respective distance D from the noise tuple that is greater than a first, predetermined limit value G as error signal windows, with the result that each error signal window represents a signal error of the measurement signal.

17. The method as claimed in claim 16, wherein the initialization phase is executed repeatedly by the processor.

18. The method as claimed in claim 16, wherein the Xth-order model is an Xth-order LPC model.

19. The method as claimed in claim 16, wherein step c) comprises the following substeps:
c.1) ascertaining for each initialization window the associated number of zero crossings in the portion of the measurement signal that is represented by the respective initialization window, and/or
ascertaining for each initialization window the associated signal energy in the portion of the measurement signal that is represented by the respective initialization window, and
c.2) determining from the M initialization windows a number of K initialization windows containing the most zero crossings as noise windows, and/or
determining from the M initialization windows a number of K initialization windows containing the lowest signal energy as noise windows.

20. The method as claimed in claim 16, wherein the method further comprises carrying out in the examination phase using the processor:
j) analyzing each error signal window using a predetermined Nth-order model and ascertaining the associated coefficients that form a fault tuple assigned to the respective error signal window, N being an integer of at least 6.

21. The method as claimed in claim 16, wherein the method further comprises carrying out in the examination phase using the processor: p1 k) dividing the fault tuples into multiple fault groups, with the result that the fault tuples in the same fault group are each at an interval from one another that is less than a second, predetermined limit value G, with the result that all error signal windows that are assigned to the same respective fault group by way of their associated fault tuples represent the same signal error.
